(19) United States
(12) Patent Application Publication
(10) Pub. No.: US 2008/0246055 A1
(43) Pub. Date: Oct. 9, 2008

(54) SEMICONDUCTOR COMPONENT INCLUDING A MONOCRYSTALLINE SEMICONDUCTOR BODY AND METHOD

(75) Inventors: Hans-Joachim Schulze, Taufkirchen (DE); Anton Mauder, Kolbermoor (DE); Armin Willmeroth, Augsburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies Austria AG, Villach (AT)

(21) Appl. No.: 11/867,411

(22) Filed: Oct. 4, 2007

(30) Foreign Application Priority Data
Oct. 4, 2006 (DE) 10 2006 047 244.6

(51) Int. Cl. H01L 29/739; H01L 29/78; H01L 21/331

(52) U.S. Cl. 257/133; 257/328; 438/135; 257/E29.262; 257/E29.197; 257/E21.382

(57) ABSTRACT

A semiconductor component comprising a monocrystalline semiconductor body, and to a method for producing the same is disclosed. In one embodiment, the semiconductor body has a semiconductor component structure with regions of a porous-mono crystalline semiconductor.

### CROSS-REFERENCE TO RELATED APPLICATIONS

This Utility Patent Application claims priority to German Patent Application No. DE 10 2006 047 244.6, filed on Oct. 4, 2006, which is incorporated herein by reference.

### BACKGROUND

The invention relates to a semiconductor component including a monocrystalline semiconductor body, in one embodiment a silicon body, wherein the semiconductor body has a semiconductor component structure. The invention furthermore relates to a method for producing the semiconductor component including monocrystalline semiconductor body, in one embodiment a silicon body, and semiconductor component structure.

A monocrystalline semiconductor body with weakly doped semiconductor circuit structures has charge carriers having a high charge carrier lifetime, such that a region of the semiconductor component structure which is flooded by charge carriers in the on-state case cannot be depleted of charge carriers rapidly enough upon changeover into the off-state case for many applications, in particular in the case of power semiconductor components, which causes various problems.

Semiconductor component structures can be connected to metallic interconnects only when corresponding contact regions of the monocrystalline silicon are highly doped. The document U.S. Pat. No. 6,888,211 B2 discloses in this respect providing a processed doping for corresponding critical contact regions in the monocrystalline semiconductor body, in one example a silicon body, by virtue of a contact region of a p-conducting well being highly doped and the space charge region of the p-conducting well being lightly doped, depending on the required reverse voltage.

Charge compensation components have particularly critical behavior since they have an extremely unfavorable dimensioning of the dopings for rapidly switching diodes. Reverse conducting IGBTs are also critical since the improvement of the diode properties can only be achieved with a simultaneously great impairment of the IGBT properties through significant homogeneous charge carrier lifetime killing. Charge compensation components are known for example from U.S. Pat. No. 4,754,310.

A high p⁺-conducting doping for avoiding latch-up below the source region has a particularly unfavorable effect in the body zone because the high doping leads to a great injection of charge carriers. The high doping constitutes a low-impedance path for holes which flow away for example during commutation or in the case of avalanche and can lead to a forward-biasing of the source-body diode as soon as the ohmic voltage drop caused by the holes in the p-type region reaches approximately 0.5 V. One consequence of such injection is the loss of the controllability of the switch in conjunction with its destruction.

Patent application DE 10 2006 006 700 describes providing, in the semiconductor component structures, charge carrier recombination zones in the vicinity of space charge regions and/or in transition regions from highly doped to weakly doped regions in order to improve the switching characteristic of the semiconductor component structures. Charge carrier recombination zones of this type shorten the charge carrier lifetime and hence the concentration of excess charge carriers in their surroundings, such that a faster changeover of the semiconductor component from one operating state to another operating state becomes possible. Moreover, a charge carrier recombination zone of this type can prevent the turn-on of parasitic transistor structures, which might otherwise lead to the destruction of the semiconductor component.

Instead of a charge carrier recombination zone, an electrically conductive region can also be introduced into the monocrystalline semiconductor body into a critical zone, its conductivity being greater than the conductivity of the surrounding silicon material. The conductive region may have a zone of higher doping or a zone with metal silicides and/or a highly doped polysilicon zone. A conductive region of this type can reduce the charge carrier lifetime down to zero and in terms of its effect provides a charge carrier recombination zone.

Patent application DE 10 2006 006 700 uses electrically conductive MAX ceramics in this respect, where M includes a transition metal, A includes an element from main group III or IV of the periodic system and X includes silicon or carbon. For an effective charge carrier recombination, gold and/or platinum is also implanted or indiffused into a monocrystalline semiconductor body. However, that is associated with the disadvantage that after such implantation processes, high-temperature processes such as are required in semiconductor fabrication can no longer be carried out since the gold and/or platinum atoms are distributed in the semiconductor body by diffusion. Furthermore, in the case of a targeted indiffusion of heavy metals, a noticeably increased leakage current is to be expected on account of the defect-dictated imperfections for the semiconductor component structure.

The charge carrier lifetime can also be reduced by irradiating the semiconductor body with electrons, as is known from the document by M. Schmitt et al. “A Comparison of Electron, Proton and Helium Ion Irradiation for the Optimization of the CoolMOS™ Body Diode”, PROC. ISPSD, Santa Fe 2002. However, this irradiation has the disadvantage that it cannot be effected selectively or locally, such that the charge carrier lifetime is reduced in the entire semiconductor body depending on the radiation dose, especially as the electron irradiation generates a laterally and vertically homogeneous profile of irradiation defects in the semiconductor body, the irradiation defects acting as charge carrier recombination centers distributed homogeneously in the semiconductor body. Moreover, the leakage current of the components can be increased to an even greater extent than in the case of the heavy metal diffusion described above.

In order to increase the switching speed of power semiconductor components, in accordance with the above document helium ions or hydrogen ions are implanted in power semiconductor components. Light ions of this type can be implanted selectively in a semiconductor body in a predetermined depth on account of the Bragg deceleration zone. This ion irradiation generates an initially monotonically rising profile of defects on their way through the monocrystalline semiconductor body, silicon body, and ends with a sharp maximum in the Bragg deceleration zone at the end of the ion range.

However, the resultant charge carrier recombination zones are also not thermostable at semiconductor process temperatures since the defects anneal at the semiconductor process temperatures in the semiconductor body as long as a relatively low irradiation dose is used in the procedure. Therefore, such irradiations for reducing the charge carrier lifetime are only carried out toward the end of the processing of the semiconductor structures of a semiconductor wafer, if impermissibly high temperatures no longer occur in the process, from the rear side and/or from the patterned top side of the semiconductor wafer. All irradiation techniques using electrons or ions without high-temperature heat treatment can additionally damage interfaces between insulators and the semiconductor and thus lead e.g., to changed or unstable threshold voltages of MOS transistors.

In order to reduce the charge carrier lifetime, agglomerated vacancy clusters in a monocrystalline silicon semiconductor body and/or precipitates of argon, oxygen and/or carbon atoms are also produced. Producing such structures in a monocrystalline semiconductor body likewise requires a high technical outlay, however, which makes the semiconductor components expensive to fabricate.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic cross section through a silicon body of a silicon wafer with a substrate region composed of porous-monocrystalline silicon.

FIG. 2 illustrates a schematic cross section through the silicon wafer in accordance with FIG. 1 after the sealing of the rear side of the silicon wafer.

FIG. 3 illustrates a schematic cross section through a silicon wafer in accordance with FIG. 1 with monocrystalline edge regions.

FIG. 4 illustrates a schematic cross section through the silicon wafer in accordance with FIG. 3 after the sealing of the rear side of the silicon wafer.

FIG. 5 illustrates a schematic cross section through a semiconductor component structure of a DMOS cell with a source terminal zone rendered porous partially in the n⁺-conducting source region.

FIG. 6 illustrates a detailed excerpt from the semiconductor component structure in accordance with FIG. 5.

FIG. 7 illustrates a schematic cross section through a semiconductor component structure of a high-voltage diode with a porous-monocrystalline silicon region in a cathode region.

FIG. 8 illustrates a schematic cross section through the semiconductor component structure from FIG. 7 with an improved edge structure of the cathode.

FIG. 9 illustrates a schematic cross section through a semiconductor component structure of a charge compensation power semiconductor component of the MOSFET type with a body zone region with porous-monocrystalline silicon region.

FIG. 10 illustrates a schematic cross section through a semiconductor component structure of an IGBT with shielding zones and a body zone region with porous-monocrystalline silicon region.

FIG. 11 illustrates a schematic cross section through a semiconductor component structure with charge carrier recombination region composed of porous-monocrystalline silicon in a body zone region.

FIG. 12 illustrates a schematic cross section through a semiconductor component structure during the introduction of a porous-monocrystalline silicon region into a body zone after the application of a gate polysilicon.

FIG. 13 illustrates a schematic cross section through a semiconductor component structure during the introduction of a porous-monocrystalline silicon region after a spacer process.

FIG. 14 illustrates a schematic cross section through a semiconductor component structure during the introduction of a porous-monocrystalline silicon region after the opening of contact windows in an intermediate oxide.

FIG. 15 illustrates a schematic cross section through a semiconductor component structure of a semiconductor diode with a porous-monocrystalline silicon region in the anode region.

FIGS. 16 to 18 illustrate schematic cross sections through semiconductor component structures during the production of a semiconductor diode.

FIGS. 19 to 22 illustrate schematic cross sections through semiconductor component structures during the production of a switching-robust semiconductor diode.

FIG. 23 illustrates a schematic cross section of a variant of an embodiment of a semiconductor diode with porous-monocrystalline silicon regions.

FIG. 24 illustrates a schematic cross section of a further variant of an embodiment of a semiconductor diode with porous-monocrystalline silicon regions.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a semiconductor component having a monocrystalline semiconductor body, in one embodiment a silicon body, which includes a semiconductor component structure and has significantly improved characteristics both with regard to contact-connection to metallic electrodes and to interconnects and with regard to an optimized charge carrier lifetime in the semiconductor component structures. Furthermore, one or more embodiments provide a method for producing such a semiconductor component.

One embodiment provides a semiconductor component including a monocrystalline semiconductor body, wherein the semiconductor body has a semiconductor component structure with regions of a porous-monocrystalline silicon.

A semiconductor component of this type has one advantage that with the porous-monocrystalline silicon regions, porous structures are provided in the monocrystalline silicon which form recombination centers for charge carriers in high concentration on their pore surfaces. If the porous-monocrystalline silicon regions are coated with a metal, then the high porosity produces an intimate anchoring between the monocrystalline silicon and the applied metal material, such that the contact resistance is significantly reduced. This, too, is one advantage of the regions of a porous-monocrystalline silicon which are provided in the monocrystalline semiconductor body. By virtue of the high number of recombination centers and the associated low charge carrier lifetime, the emitter effect of porous-monocrystalline layers remains low despite a high doping. A further advantage is that the porous-monocrystalline silicon regions do not change their structure and properties even during subsequent high-temperature processes, such that the porous-monocrystalline silicon regions can be provided in the monocrystalline silicon semiconductor body at an optimum point in the fabrication sequence for producing a semiconductor component.

In a first embodiment of the invention, the semiconductor component structure has a substrate region composed of porous-monocrystalline and highly doped silicon. A substrate region of this type forms a basic material having a possible dopant concentration which in previous silicon substrates is upwardly limited to a range of up to approximately 10¹⁹ atoms per cm³ and can now be significantly increased. By using a more highly doped basic material such as becomes possible by using a porous-monocrystalline substrate region, it is possible for example to significantly reduce the on resistance of field-effect-controlled semiconductor components such as MOSFETs and IGBTs or diodes.

Another advantage of providing a substrate region composed of porous-monocrystalline and highly doped silicon is that the previous restriction to dopant concentrations during the crystal growth of monocrystalline semiconductor bodies in order not to impede the monocrystalline growth of the semiconductor body and to keep the defect density as low as possible can be overcome. For this purpose, a substrate region composed of porous-monocrystalline semiconductor can now subsequently be provided with a high dopant concentration up to 10²¹ cm⁻³ from the rear side of a semiconductor wafer, in one embodiment a silicon wafer. In this case, it is an advantage if the majority of the semiconductor wafer is etched in porous fashion from the rear side and only a thin region of the monocrystalline semiconductor body remains, onto which can then be grown for a semiconductor structure an epitaxial layer or else a multiplicity of epitaxial layers with subsequent patterning of the epitaxial layers.

Moreover, it is now possible, before the actual production of a substrate region composed of porous-monocrystalline and highly doped silicon, to produce the epitaxial structures on the top side of the silicon wafer and subsequently to drive the etching in porous fashion as far as the boundary with respect to the epitaxial layers, such that in principle the entire monocrystalline-pulled region of the silicon substrate is converted into porous-monocrystalline material. In addition, it is possible to carry out the doping of the porous-monocrystalline substrate region subsequently by using a doping process by indiffusion for example by using a gas phase diffusion or a vacuum diffusion of impurities into the porous-monocrystalline silicon material. In this case, that side of the silicon wafer which is not rendered porous can be protected with a masking layer.

In the case of gas phase diffusion, e.g., a POCl₃ diffusion or a phosphine diffusion is appropriate for producing n-doped material. Electrically active concentrations of above 10²⁰ cm⁻³ can be produced in the case of a diffusion of this type. By contrast, if the intention is to produce p-doped silicon wafers, it is possible to provide e.g., a diborane diffusion or a solid source diffusion with boron nitride wafers. Other doping methods such as “Spin-On” or solid powder sources can also enable the desired high doping of the porous-monocrystalline substrate region of the silicon wafer. What is more, this region of high dopant concentration in the porous-monocrystalline substrate region extends further, given the same temperature budget, than in the case of the indiffusion of the doping into a purely monocrystalline semiconductor substrate.

A further advantage is that excessively high diffusion temperatures or excessively long diffusion times are not required for the doping of the porous-monocrystalline substrate region, especially as the dopant can penetrate through this region very rapidly via the pores produced, wherein high dopant concentrations can be set.

In addition, a porous-monocrystalline and highly doped substrate region of this type has outstanding gettering properties, particularly if the region is highly doped with phosphorus atoms. If necessary, the region can also be removed again relatively easily at the end of a process, especially as it has a significantly higher etching rate than the normal silicon wafer. Such a gettering porous-monocrystalline substrate region can be provided for example on the rear side of a MOSFET or else of power thyristors, wherein a substrate region of this type, for gettering purposes, can be produced at the beginning of the production process or else relatively late in the fabrication process. Consequently, undesired impurities, in particular heavy metal impurities, which indiffuse into the silicon wafer during the fabrication process or else are already present in the starting wafers can be subjected to gettering with the porous-monocrystalline substrate region.

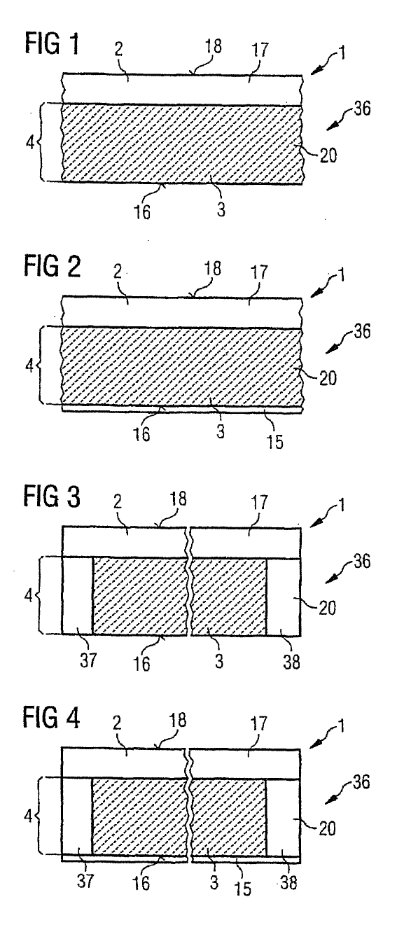

In addition, it is possible to subject that part of the silicon wafer which is not rendered porous to a thinning method such as a CMP method (chemical mechanical polishing) or a grinding and/or etching method from the top side before corresponding epitaxial structures for the semiconductor component structure are applied to the top side. On the other hand, it is also possible to seal that substrate region of the rear side of the semiconductor wafer which is rendered porous by depositing a layer in order to ensure that no outdiffusion of the dopant and hence also no contamination of downstream fabrication apparatuses with the dopant of the porous-monocrystalline and highly doped substrate region takes place during subsequent fabrication processes. It is likewise conceivable to seal the wafer rear side by using a laser fusion process. Further variants for fabricating a porous-monocrystalline substrate region are explained in more detail with reference to FIGS. 1 to 4 below.

In a further embodiment, the semiconductor component structure has a partial source region of a source terminal zone of a MOSFET with porous-monocrystalline and highly doped silicon. An n-conducting source terminal zone or an n-conducting emitter terminal zone in a power semiconductor component is intended, on the one hand, to have an emitter efficiency that is not excessively high and, on the other hand, to supply a very good contact resistance. Since a minimum edge concentration of an n-conducting region for an ohmic contact is typically a few 10¹⁹ doping atoms per cm³, the efficiency of such an emitter is generally already very good. Although this entails low conduction losses, on the other hand it also entails an undesired high susceptibility to a “latch-up” in the case of MOS cells e.g., in a MOS transistor or in an IGBT (Insulated Gate Bipolar Transistor). The “latch-up” effect and also the associated parasitic thyristor and bipolar structures in MOSFET and IGBT are described e.g., in U.S. Pat. No. 4,364,073. In the case of bipolar semiconductor components such as diodes, thyristors or GTOs, by contrast, the strong n-type emitter can lead to undesirably high turn-off losses on account of its strong charge carrier injection.

In order to reduce the effects of an “excessively good” n-conducting emitter, it is already known, as described in the introduction, to perform a targeted reduction of the charge carrier lifetime, to be precise homogeneously and/or inhomogeneously in the vertical component direction. However, the measures mentioned in the introduction have significant disadvantages in comparison with the invention's provision of a partial source region of a source terminal zone of a MOSFET or of an IGBT with porous-monocrystalline and highly doped silicon and/or the provision of a partial or whole-area emitter region of a bipolar semiconductor component with porous-monocrystalline and highly doped silicon. For this purpose, a layer sequence is produced which includes a highly n-doped porous-monocrystalline silicon layer, below which a more weakly n-doped silicon layer can follow in the monocrystalline silicon body.

A layer sequence of this type affords one advantage that the highly doped porous-monocrystalline silicon layer enables, on the one hand, a very low contact resistance and enables, on the other hand, on account of the pores present in this layer or in this region, a greatly increased surface charge carrier recombination which considerably reduces the emitter or source efficiency of this layer system for a source terminal zone or an emitter terminal zone, respectively. The intensity of the emitter effect of the source terminal zone or of the n-type emitter is controlled in particular by using the dopant concentration and the vertical extent of the more weakly n-doped zone arranged, if appropriate, below the porous-monocrystalline silicon region. An n-conducting source region or n-conducting emitter region provided in this way can be used particularly in the case of MOSFETs or in the case of IGBTs or in the case of bipolar semiconductor components.

In a further embodiment, the semiconductor component structure has a partial body zone region in a MOSFET or in an IGBT with porous-monocrystalline silicon. MOSFETs and IGBTs have critical operating states if they are flooded with charge carriers by the conducting body diode and are commutated into the off state. In this case, the charge carriers must be removed from the drift region by using the electric field before a reverse voltage can be built up.

The provision of the partial body zone region according to the invention in a MOSFET or IGBT with porous-monocrystalline silicon, which undergoes transition in the vertical direction to a medium doped p-conducting monocrystalline region of the body zone, makes it possible to produce a local charge carrier recombination center since increased recombination of charge carriers occurs as a result of the high surface area proportions of the pores, for which reason the region does not contribute significantly to the flooding with charge carriers despite a high doping.

In a further configuration of the invention, only a part of the p⁺-type region or of the p-doped body region below the p⁺-type region is rendered porous, such that a low-impedance path for the flowing away of holes directly below the source region is not impaired, but an effective local charge carrier recombination zone is indeed provided for the flooding with charge carriers.

The p-type well required for the body zone can be embodied with an implantation dose of approximately 5×10¹² cm⁻² to approximately 3×10¹⁴ cm⁻², depending on the intended magnitude of the threshold voltage of the transistor. Since the porous-monocrystalline silicon can be embodied in highly p⁺-doped fashion, the ohmic losses in this region are very small and the doping region still counteracts a latch-up of the MOS power transistor. In addition, however, electrons injected into the porous-monocrystalline p⁺-type region from the source region recombine significantly faster. This means that the probability of latch-up is reduced further.

In one embodiment, the dose of the p-type body outside the region that is rendered porous is still at least 1.6×10¹² cm⁻², that is to say at least the breakdown charge, in order that the electric field in the off-state case is completely reduced before the layer that is rendered porous. Otherwise, increased leakage currents could occur if the electric field advances statically as far as the pores of the porous-monocrystalline silicon and extracts and separates the charge carriers produced by generation at the interfaces. Consequently, this embodiment of the invention, in which a partial body zone region is provided with porous-monocrystalline silicon, has significant advantages over known semiconductor component structures of the MOSFET and/or IGBT type.

In a further embodiment of the invention, the semiconductor component structure has a partial or whole-area drain region of a drain terminal zone of a MOSFET or a partial or whole-area collector region of a collector terminal zone of an IGBT with porous-monocrystalline and highly doped silicon. These porous-monocrystalline and highly doped silicon regions are provided on the rear side of a semiconductor component and can already be introduced into the substrate of a semiconductor wafer.

This is associated with an advantage that a significantly low-impedance contact to a drain or collector electrode can be produced by this porous-monocrystalline and highly doped silicon layer being metallized. Moreover, a drain terminal zone with n-conducting dopant composed of phosphorus has the advantage that a high gettering effect is formed in the substrate region. Undesired impurities which have indiffused into the silicon wafer during the fabrication process or else are already present in the starting wafer are thereby subjected to gettering. Finally, the porous-monocrystalline and highly doped drain terminal zone has the advantage that the substrate resistance of a semiconductor component is significantly reduced if the zone is extended into the vicinity of the drift path of a semiconductor component.

In a further embodiment, the semiconductor component structure has a partial or whole-area anode region of a semiconductor diode, in particular for use as a rapidly switching diode or as a freewheeling diode with porous-monocrystalline and highly doped silicon.

A semiconductor diode with a porous-monocrystalline and highly doped silicon region makes it possible to keep the efficiency of the anode emitter low. This results in lesser flooding of the n⁻-type zone with charge carriers at the anodal end and hence a smaller reverse current peak during commutation as a result of the provision of a partial or whole-area anode region with porous-monocrystalline and highly doped silicon. The low degree of flooding with charge carriers and the small reverse current peak have a favorable effect on low switching losses, which is an advantage, particularly in the case of rapidly switching diodes or in the case of freewheeling diodes.

What is more, the high doping of the porous-monocrystalline anode region provides for reliable ohmic contact-making with low contact resistances. For this purpose, the contact region of the anode in the semiconductor diodes according to the invention is produced from the porous-monocrystalline silicon material. Increased charge carrier recombination occurs as a result of the high surface area proportions of the pores, for which reason this region does not contribute significantly to flooding despite a high doping. For the p-conducting well of the anode, a dose just above the breakdown charge of approximately 2×10¹² cm⁻² suffices in comparison with the prior art because it is only in the static case that the electric field is not intended to come as far as the porous-monocrystalline silicon region, in order to ensure a low leakage current. In the dynamic case, the electric field is permitted to reach as far as the porous-monocrystalline silicon and will generate an additional leakage current. Since the latter flows only momentarily and is also significantly smaller than the reverse current, which has typical current densities in the range of 50 to 300 Acm⁻², these losses as a result of the additional leakage current are negligible.

Since the porous-monocrystalline silicon in this embodiment of the invention is embodied in highly p⁺-doped fashion, the ohmic losses in this region are negligible. What is furthermore advantageous about this embodiment is a noncritical contact resistance in comparison with present-day contact implantations, in which fluctuations in the contact resistance for example with respect to an aluminum contact-connection can already occur at implantation doses of less than 1×10¹³ cm⁻². A further advantage is that the porous-monocrystalline silicon anode region can be embodied with a thickness such that customary defects or slight spikes of the metallization are completely covered and do not have an adverse effect.

A further embodiment provides for the semiconductor component structure to have a partial or whole-area cathode region of a power diode with porous-monocrystalline and highly doped silicon. In this case, too, a high doping for the porous-monocrystalline silicon layer is provided for an ohmic contact-making in the cathode region, in order to decouple the cathode emitter effect that otherwise usually occurs in the case of high dopings. For this purpose, the porous-monocrystalline silicon region can be provided in the entire central contact region of the cathode, while the edge region with the rear side of the silicon chip is protected against the formation of a porous-monocrystalline structure and the high doping.

In a further embodiment, the semiconductor component structure has a protective ring region of a power diode with porous-monocrystalline and highly doped silicon. Protective rings of this type are customary in power diodes in order to prevent creepage currents on the top side of the monocrystalline silicon material. The introduction of a partial protective ring region with porous-monocrystalline and highly doped silicon on the one hand produces a charge carrier recombination zone and on the other hand improves the ohmic contact to the metal contact of the protective ring.

For diodes having particularly high switching robustness, it can be provided that the anode metal ends laterally far before the end of the anode doping. In addition, an edge field plate is provided in the edge region of the anode region, and makes contact with the p-conducting well of the edge region of the anode via a partial porous-monocrystalline silicon region. This reduces the injection of charge carriers into the edge region of the freewheeling diode on account of the high lateral bulk resistance in the anode, which improves the switching robustness.

A lateral grading is provided, including a highly doped porous-monocrystalline silicon region for the anode metal, a laterally adjacent weakly doped porous-monocrystalline silicon region for increasing the switching robustness and a laterally adjacent again highly doped porous-monocrystalline silicon region for the connection of the field plate metal, and a weakly doped monocrystalline silicon region arranged in the outermost edge region of the p-conducting anode material. Alongside this grading in the p-conducting anode region of the high-voltage diode, it is possible to provide in addition in the edge region of the monocrystalline silicon chip a p-conducting protective ring or a plurality of p-conducting protective rings which are in turn connected to the associated metallic protective ring via a porous-monocrystalline silicon region having a high doping.

A method for producing a monocrystalline silicon wafer for semiconductor components with semiconductor component structures having regions composed of porous-monocrystalline silicon has the following method processes: firstly, a prepatterning of a silicon wafer with semiconductor component structures can be effected. Afterward, regions of the prepatterned silicon wafer which are not intended to have a porosity are covered with a protective layer structure. This is followed by an anodic oxidation with simultaneous porous etching removal of the monocrystalline silicon material to form pores in the monocrystalline silicon wafer in the non-covered regions of the silicon wafer. Afterward, the protective layer structure can be removed and a final patterning of the silicon wafer to form semiconductor component structures with regions composed of porous monocrystalline silicon can be carried out.

This method has an advantage that the rendering porous process, on account of its high-temperature suitability, can be carried out at an expedient point in time in the overall method for producing a semiconductor component. In particular there is freedom of choice as to whether the lightly doped region of a p-conducting well, for example, is intended to be rendered porous and the high p⁺-type doping is subsequently introduced by using ion implantation or gas phase diffusion, for example, or alternatively a previously highly doped region of a semiconductor wafer is subsequently rendered porous by using the abovementioned method processes.

Since an anodic oxidation and also the simultaneous porous etching removal can be carried out with the aid of the protective layer structure selectively both on the rear side of the semiconductor wafer and on the top side of the semiconductor wafer, it is possible to provide the porous-monocrystalline silicon regions on contact areas of the silicon top side and/or on an entire substrate region from the rear side with pores in the monocrystalline silicon material.

A method for producing a semiconductor component with semiconductor component structures having regions composed of porous-monocrystalline silicon is firstly carried out with the same method processes for a silicon wafer, in which case, after a final patterning of the silicon wafer to form semiconductor component structures with regions composed of porous-monocrystalline silicon, the silicon wafer is separated into individual silicon chips. The individual silicon chips can subsequently be introduced into a semiconductor component housing with electrodes of the silicon chip being connected to external contacts of the housing.

In one configuration of the method, for rendering a substrate region porous, the rear side of the semiconductor wafer is subjected to anodic oxidation and etched in porous fashion, edge regions of the silicon wafer being provided with a protective layer structure in order to improve the dimensional stability and not being exposed to the porous etching removal.

It is furthermore provided that, for rendering a substrate region of the silicon wafer porous, firstly a semiconductor component structure based on epitaxial layers of the top side of the silicon wafer is completed and then the rear side of the silicon wafer is subjected to anodic oxidation and is etched in porous fashion. This method variant is used for semiconductor components whose semiconductor component structures are introduced in epitaxial layers on the top side of a monocrystalline semiconductor wafer. In this method variant, it is only after completion of the epitaxial layers or the semiconductor component structures on the top side of the semiconductor wafer that the porosity of the substrate is produced from the rear side of the semiconductor wafer and a correspondingly high doping is introduced into this porous substrate region.

In a further configuration of the method, a body zone region of a MOSFET is rendered porous partially to form a charge carrier recombination zone after a patterning of a gate polysilicon layer. For this purpose, the gate polysilicon layer is provided with a protective layer structure in order that selectively only the body zone regions in which a source contact is intended to be positioned are partially patterned to form a porous-monocrystalline silicon region and doped.

The doping of regions partially to be etched in porous fashion is typically effected after the application of the protective layer structure and before the rendering porous process. This results in a clear, almost planar boundary between the material that is rendered porous and the monocrystalline silicon material that is not rendered porous. Conversely, if a doping of regions partially etched in porous fashion is effected after the rendering porous process, it is necessary to reckon with the occurrence of a relatively fissured transition zone between highly doped and lightly doped silicon in the monocrystalline silicon region of the semiconductor component structure.

As already mentioned above, on account of the high-temperature suitability of the porous-monocrystalline silicon region, the region can be produced in different fabrication processes. Thus, a body zone region of a MOSFET will be rendered porous partially after a spacer process. This process of partially rendering porous the body zone region of the MOSFET can also be effected after an introduction of contact windows into an intermediate oxide. A selective introduction of a porous-monocrystalline silicon region in the semiconductor component structures is possible without any problems in both cases.

In a further exemplary implementation of the method, it is provided that an anode region and/or a field plate terminal region of a semiconductor diode is rendered porous partially or over the whole area after the introduction of a p-conducting anode region into the top side of a semiconductor body, in one example a silicon body, and before the metallization of the anode and/or the field plate. This reduces the anode emitter efficiency, on the one hand, and increases the switching robustness of a semiconductor diode, on the other hand. For this purpose, a weakly doped p-conducting region between an anode and a field plate terminal can be etched in porous fashion before a metallization of anode and field plate.

Furthermore, it is possible that a cathode region of a semiconductor diode is rendered porously partially or over the whole area after the introduction of an n-conducting cathode region into the rear side of a semiconductor body, in one example a silicon body, and before the metallization of the cathode. In this case, too, the porous-monocrystalline silicon region having a high doping serves to reduce the contact resistance between cathode electrode and monocrystalline silicon region.

Hydrofluoric acid and an alcohol, in particular ethanol, can be used for an anodic oxidation. In order to carry out a porous etching simultaneously with the anodic oxidation, it is possible to use an anodic bath with 15 molar C₂H₅OH and 5 molar HF or an anodic bath with 10.3 molar C₂H₅OH and 11.7 molar HF. An irradiation with light may be necessary or useful particularly in the case of n-doped semiconductor material. In order to cover the regions of the prepatterned silicon wafer which are not intended to have a porosity, it is possible to selectively apply a protective layer structure composed of a resist layer or a silicon nitride layer.

In many cases it is advantageous, after the production of the porous-monocrystalline silicon regions, to cover and/or to mask the regions. For this purpose, a polysilicon layer, a silicon oxide layer, a silicon nitride layer or a layer stack of such layers is applied to the regions etched in porous fashion. A sealing of the regions is thus achieved, such that a contamination with the dopant in the regions does not contaminate the corresponding apparatuses during subsequent high-temperature fabrication processes. Moreover, it is possible for these porous regions to be superficially sealed by using laser fusion.

In order to remove the protective layer structure composed of a resist layer, it is also possible to use a solvent or it is possible to carry out a plasma ashing in order to remove the protective layer structure after the rendering porous process has been effected.

FIG. 1 illustrates a schematic cross section through a silicon body 1 of a silicon wafer 36 with a substrate region 4 composed of porous-monocrystalline silicon 3 in accordance with one embodiment of the invention. A substrate 20 of this type is associated with the possibility of minimizing the substrate resistance of semiconductor component structures 2 to a greater extent than is possible in the case of a conventional semiconductor substrate 20 doped by using a single-crystal growing process. The silicon wafer 36 can be provided with open pores from the rear side 16 with the aid of an anodic oxidation with simultaneous pore etching, monocrystalline silicon material remaining, which can then be occupied with an extremely high impurity concentration of more than 10²⁰ cm⁻³ along the pores for example by using a gas phase diffusion with phosphorus oxytrichloride (POCl₃) or phosphine, such that an n⁺-conducting substrate region 4 arises.

In order to produce a p⁺-conducting substrate region 4, it is possible to carry out a gas phase diffusion by using diborane and/or a gas phase diffusion with the aid of a solid source such as boron nitride. Alongside the effect that a low substrate resistance is thereby available, the residual monocrystalline layer on the top side 18 of the semiconductor wafer 36 can be used for constructing a semiconductor component structure 2, especially as the porous-monocrystalline silicon region 3 of the substrate 20 has a high-temperature durability.

In the case of a phosphorus doping of the porous-monocrystalline substrate region 4, the high phosphorus doping exhibits a gettering effect for impurities that are present in the monocrystalline semiconductor silicon or are introduced by further method processes. Finally, a metallization can be carried out on the rear side 16, which metallization leads to a low-impedance contact having good conductivity between the contact metal and the porous-monocrystalline silicon 3. Furthermore, the porous structure of the substrate region 4 will give rise to an intimate mechanical intermeshing between metal and the porous-monocrystalline silicon region 3.

FIG. 2 illustrates a schematic cross section through the silicon wafer in accordance with FIG. 1 after the sealing of the rear side 16 of the silicon wafer 36. For this purpose, a polysilicon layer or a silicon oxide layer or a silicon nitride layer or a layer stack of the layers is applied as protective layer structure 15 to the rear side 16 of the highly doped substrate region 4 etched in porous fashion. In addition, it is possible to seal the rear side 16 by laser fusion of the rear side 16 of the semiconductor wafer 36 with the porous-monocrystalline substrate region 4.

Furthermore, it is possible to apply epitaxial layer structures 17 before the actual introduction of the porous-monocrystalline silicon substrate region 4 on the silicon wafer in order thus to realize drift zones and/or charge compensation zones for power semiconductor components, and only afterward to produce the porosity of the silicon substrate region 4 from the rear side 16.

FIG. 3 illustrates a schematic cross section through a silicon wafer 36 in accordance with FIG. 1 with monocrystalline edge regions 37 and 38 of the silicon wafer 36 in the substrate region 4. The monocrystalline silicon edge regions can serve for increasing the stability of the silicon wafer 36. The edge regions 37 and 38 can also be provided in the semiconductor chip positions of the silicon wafer 36.

FIG. 4 illustrates a schematic cross section through the silicon wafer 36 in accordance with FIG. 3 after the sealing of the rear side 16 of the silicon wafer 36. Components having the same functions as in the previous figures are identified by the same reference symbols and are not discussed separately. In this case, the protective layer structure 15 corresponds to the sealing layer that has already been discussed above. On the other hand, it is also possible to arrange, instead of the protective layer structure 15, a metallization for a rear side cathode, a rear side drain electrode and/or a rear side collector in accordance with the semiconductor component structure 2 with an improved contact transition between metal and semiconductor material on the porous-monocrystalline substrate region 4.

FIG. 5 illustrates a schematic cross section through a semiconductor component structure 2 of a DMOS cell with an n⁺-conducting source region 5 which is rendered porous partially or completely and which projects with its source terminal zone 6 into a p-conducting body zone 7. With the aid of a gate electrode G and a gate oxide layer 40, an electrically conducting channel is activated between an n⁺-conducting region of the source electrode S via an n-conducting drift path 44 to an n⁺-conducting region of the drain electrode D, which is arranged on the rear side 16, via the p-conducting body zone. For this purpose, after the patterning of a gate polysilicon 21 or after a contact hole etching, the n⁺-conducting region on the semiconductor surface is rendered porous. It is thus possible to introduce the required dopant concentration for a low-impedance contact on the n⁺-conducting source region without this quantity of dopant being able to bring about an appreciable emitter effect for the p-type body region on account of the high surface recombination. The source and/or body zones that are rendered porous can also be used for lateral MOSFETs, which is not illustrated in the figures.

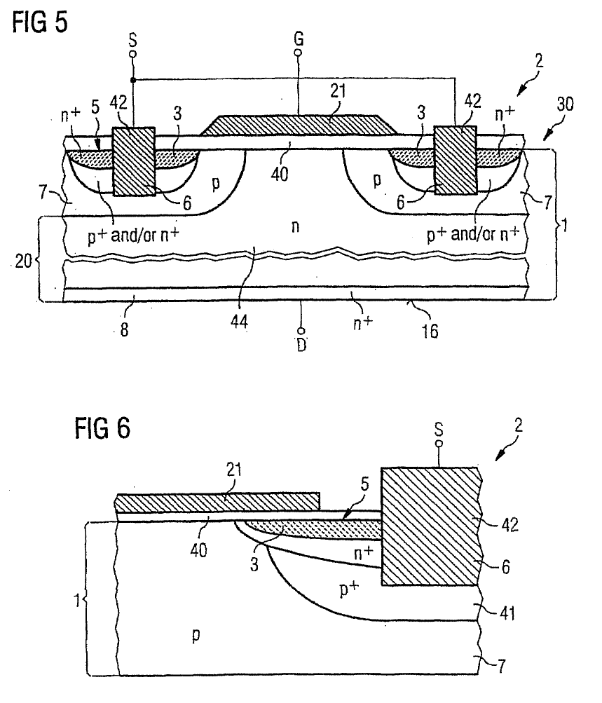

FIG. 6 illustrates a detailed excerpt from the semiconductor component structure in accordance with FIG. 5. Components having the same functions as in FIG. 5 are identified by the same reference symbols and are not discussed separately. The detail drawing concerns only the region of the body zone 7 in the monocrystalline silicon body 1 and the source terminal zone 6 projecting into the body zone 7, wherein the source region 5 is constructed in three stages and undergoes transition from an n⁺-conducting porous-monocrystalline silicon region into an n⁺-conducting monocrystalline source region, adjacent to which is a highly doped p⁺-conducting region 41 of the body zone 7, into which projects the metallization 42 of the source electrode S.

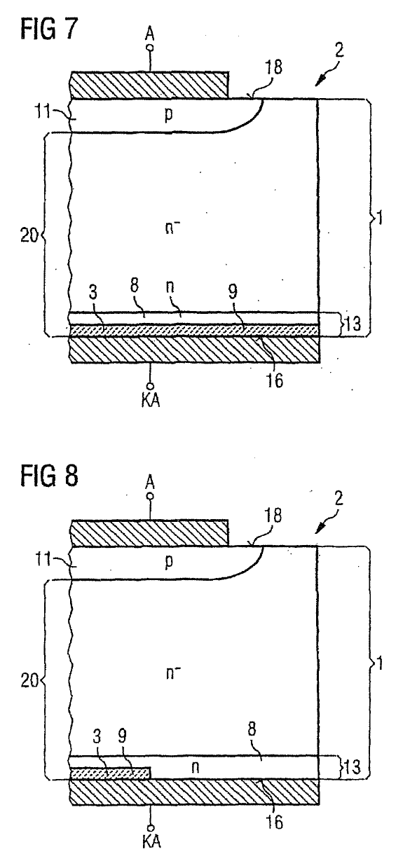

FIG. 7 illustrates a schematic cross section through a semiconductor component structure 2 of a high-voltage diode with a porous-monocrystalline silicon region 3 in a cathode region 13 on the rear side 16 of the silicon body 1 for the high-voltage diode. For this purpose, the substrate 20 largely includes a weakly doped n⁻-conducting monocrystalline silicon substrate 20, on the top side 18 of which a p-conducting anode region 11 is introduced, which can be connected to an anode potential via an anode electrode A. A metallization for a cathode electrode KA is arranged on the porous-monocrystalline silicon region 3 introduced into an n-conducting layer on the rear side 16 of the monocrystalline semiconductor body 1.

FIG. 8 illustrates a schematic cross section through the semiconductor component structure 2 of FIG. 7 with an improved edge structure of the cathode. In order to avoid creepage currents in the edge region of the high-voltage diode, a porosity in the cathode region 13 is dispensed with in the edge region of the diode.

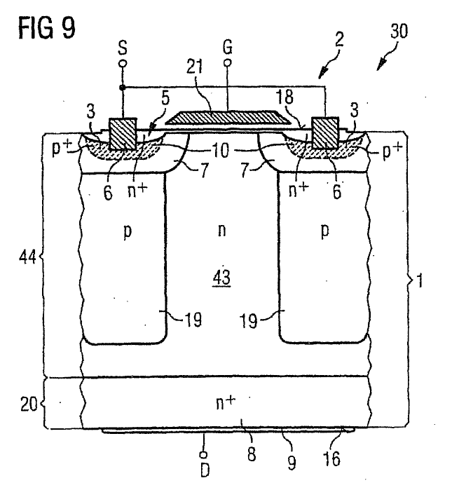

FIG. 9 illustrates a schematic cross section through a semiconductor component structure 2 of a charge compensation power semiconductor component of the MOSFET type 30 with a body zone region 7 having a porous-monocrystalline silicon region 3. For this purpose, the porous-monocrystalline silicon region 3 is arranged into a p⁺-conducting region of the body zone 7 below the source terminal zone 6. A drift path including n-conducting drift zones 43 and p-conducting charge carrier compensation zones 19 is adjacent to the body zone 7 in the vertical direction. The drift path 44 undergoes transition into the substrate region 4, adjacent to which on the rear side 16 is a drain region 8 with drain terminal region 9 of the drain electrode D. Components having the same functions as in the previous figures are identified by the same reference symbols and are not discussed separately.

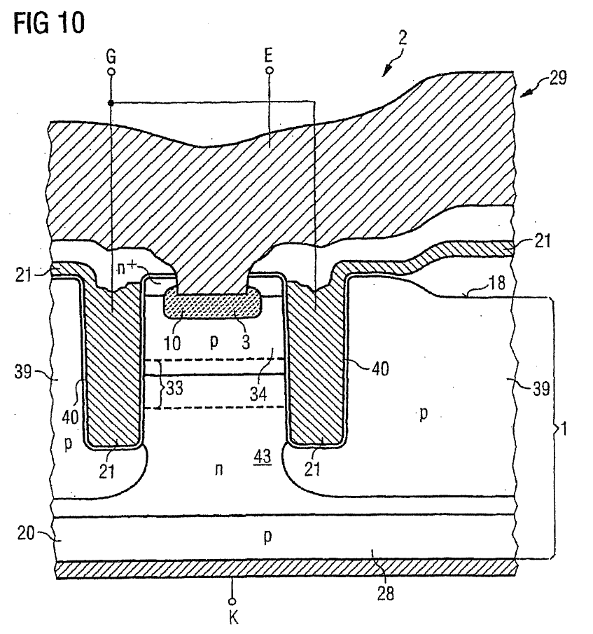

FIG. 10 illustrates a schematic cross section through a semiconductor component structure 2 of an IGBT 29 with shielding zones 39 and a body zone region 7 having a porous-monocrystalline silicon region 3. The IGBT 29 has a gate structure 31, which is arranged in a trench structure 32 and which extends vertically with respect to the body zone 7 and a drift zone 43 of a drift path. The walls of the trench structure 32 are covered with a gate oxide layer 40 and filled with a gate polysilicon material. The polysilicon material undergoes transition into a polysilicon layer 21 which connects the gate structures to one another. The porous-monocrystalline silicon region 3 is arranged as charge carrier recombination zone 10 above the space charge region 33 of the pn junction from body zone 34 to drift zone 43.

An ohmic contact to the emitter metallization of the emitter electrode E of the IGBT is simultaneously produced by the porous-monocrystalline silicon region 3. The substrate region 4 has a p⁺-conducting collector zone 28, on which the collector electrode K is metallized, in the lower region on the rear side 16 of the silicon body 1. In this case, too, it may be useful to transform the collector zone 28 at least partly into a porous-monocrystalline silicon region 3. On the other hand, it is advantageous to arrange a porous-monocrystalline silicon region in the region of a region of an IGBT or of a MOS power component that is jeopardized by a parasitic bipolar transistor. Finally, porous-monocrystalline silicon regions 3 can be arranged as charge carrier recombination zones in integrated circuits at positions jeopardized by shunt current.

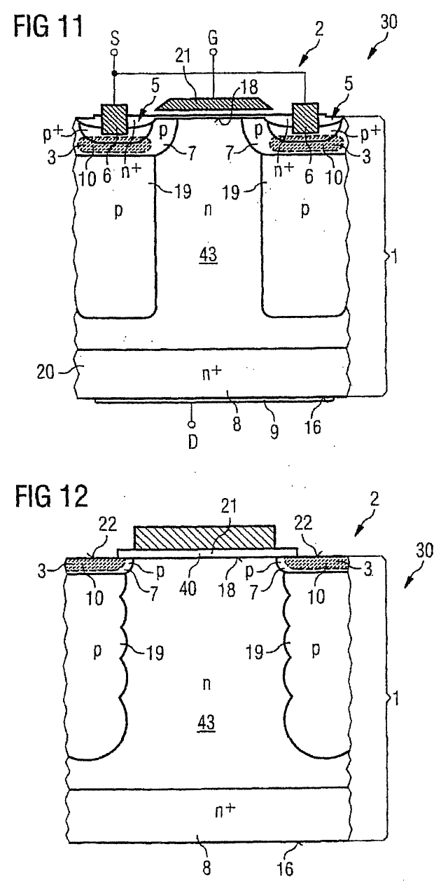

FIG. 11 illustrates a schematic cross section through a semiconductor component structure 2 with charge carrier recombination region 10 composed of porous-monocrystalline silicon. The semiconductor component structure 2 corresponds to the semiconductor component structure 2 in FIG. 9. However, the porous-monocrystalline silicon region 3 is not arranged directly adjacent to an n⁺-conducting source region as in FIG. 9, but rather in a transition region between a p⁺-conducting region and a p-conducting region of a body zone 7. The porous-monocrystalline silicon region 3 thus serves exclusively for charge carrier recombination in the body zone 7, whereby the flooding of the n-conducting drift zone is reduced and a faster switching behavior of the MOSFET component as is illustrated in FIG. 11 is achieved.

FIGS. 12 to 14 illustrate different possibilities, on the basis of the high-temperature stability of the porous-monocrystalline silicon region, for realizing introduction of the region after different fabrication processes.

In this respect, FIG. 12 illustrates a schematic cross section through a semiconductor component structure 2 upon introduction of a porous-monocrystalline silicon region 3 into a body zone 7 after the application of the gate polysilicon 21. For this purpose, corresponding contact windows 22 are introduced into the gate oxide layer 40 in order to carry out the anodic oxidation and the porewise etching from there. Since the gate oxide electrode 40 is relatively thin, it can possibly be removed during the production of the porous-monocrystalline silicon region without introducing contact windows 22 beforehand. However, all regions which are not intended to be etched in porous fashion are provided with a resist layer structure or protective layer structure beforehand, in order to ensure that the already existing structures are not subjected to an etching attack.

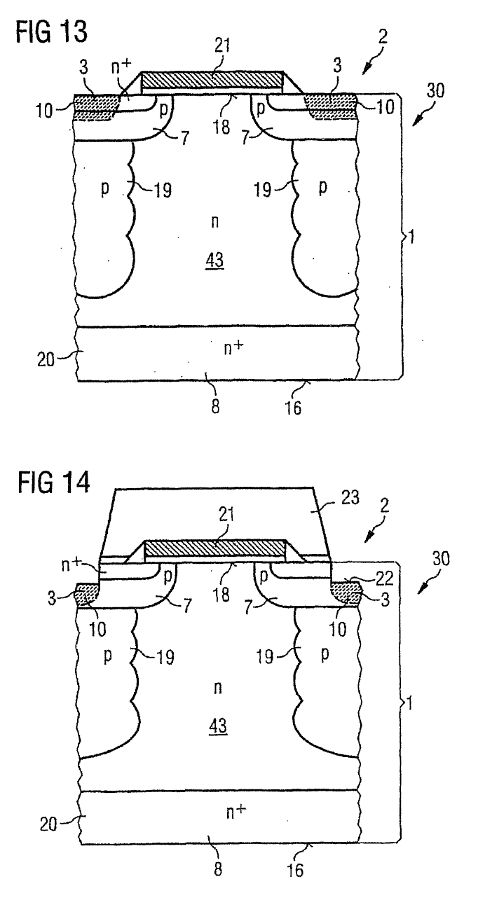

FIG. 13 illustrates a schematic cross section through a semiconductor component structure 2 upon introduction of a porous-monocrystalline silicon region 3 after a spacer process of a charge compensation component. In the spacer process, an insulation layer is arranged onto the edges of the gate electrode, which insulation layer can simultaneously serve as masking for the anodic oxidation process with simultaneous etching progression. In this case, the n⁺-conducting layer for the source region 5 has already been introduced, such that the n⁺-conducting layer and the p-conducting region of the body zone 7 are provided with a porous-monocrystalline silicon region 3.

FIG. 14 illustrates a schematic cross section through a semiconductor component structure 2 upon introduction of a porous-monocrystalline silicon region 3 after the opening of contact windows 22 in an intermediate oxide 23 in the case of a charge compensation component. Upon introduction of the contact windows 22, the pn junction between an n⁺-conducting source region 5 and a p-conducting body zone region 7 is simultaneously uncovered, such that the porous-monocrystalline silicon region 3 is now arranged completely in the body zone 7. The metallization for the source electrode is subsequently carried out on this contact window 22 prepared in this way.

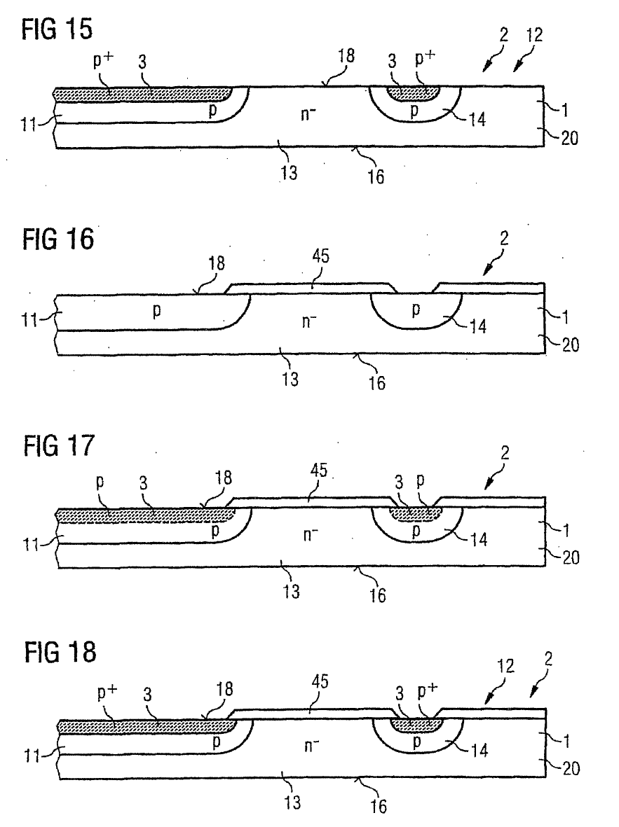

FIG. 15 illustrates a schematic cross section through a semiconductor component structure 2 of a semiconductor diode, in particular of a rapidly switching diode or of a freewheeling diode 12 with a porous-monocrystalline silicon region 3 in the anode region 11. The advantages of this semiconductor component structure 2 have already been discussed above and a renewed discussion is therefore dispensed with. The porous-monocrystalline silicon region 3 is introduced not only into the p-conducting region of the anode 11 but also into the p-conducting region of a protective ring region 14, which forms the edge termination for high-voltage diodes. A cathode region 13 is provided on the rear side 16 of the silicon body 1, such that the cathode can be applied areally on the rear side 16 of the silicon body 1.

FIGS. 16 to 18 illustrate schematic cross sections through a semiconductor component structure 2 during the production of a semiconductor diode, in particular a rapidly switching diode or a freewheeling diode 12.

FIG. 16 illustrates the schematic cross section of a section of a silicon body 1 having a rear side 16 and a top side 18, into which a semiconductor diode structure is to be introduced. For this purpose, a patterned oxide layer 45 is applied to the top side 18, which only leaves free windows for introducing p-conducting wells for the anode region 11 and the protective ring region 14. Boron atoms are then introduced into the n-conducting silicon body 1 composed of monocrystalline silicon material, which boron atoms introduce a correspondingly deep anode region 11 and also a correspondingly deep protective ring region 14 into the semiconductor body 1. The same patterned oxide layer 45, if it acts in a sufficiently insulating manner, can subsequently be used to introduce partially from the top side 18, both in the anode region 11 and in the protective ring region 14, the monocrystalline silicon material into porous-monocrystalline silicon regions 3 by anodic oxidation with simultaneous etching in a depth that is smaller than the depth of the anode region 11 and of the protective ring region 14.

FIG. 17 illustrates a schematic cross section after the introduction of the porous-monocrystalline silicon regions into the top side 18 of the monocrystalline silicon body 1. In this case, this region initially still has the low doping of the anode region 11 and of the protective ring region 14.

FIG. 18 illustrates a schematic cross section through the semiconductor component structure 2 after the production of a semiconductor diode 12. For this purpose, a high p⁺-conducting dopant concentration was introduced once again under the protection of the patterned oxide layer 45 in the region of the porous-monocrystalline silicon region 3. This ensures, on the one hand, that the anode emitter efficiency is reduced on account of the charge carrier recombination centers arranged on the surfaces of the pores. On the other hand, a low-impedance contact to the anode A and to the metallic protective ring now also becomes possible on account of the high doping.

For the p-conducting well, a dose just above the breakdown voltage of approximately 2×10¹² cm⁻² suffices in this embodiment of the invention in comparison with the prior art because it is only in the static case that the electric field is not intended to reach as far as the porous-monocrystalline silicon 3, in order to ensure a lower leakage current. In the dynamic case, the electric field is permitted to reach as far as the porous silicon and will then generate additional leakage current. However, since the latter flows only momentarily and is also significantly smaller than the reverse current, which has typical current densities in the range of 50 to 300 Acm⁻², these additional losses are negligibly small.

Since the porous-monocrystalline silicon can be doped in highly p-conducting fashion, the ohmic losses in this region are likewise negligible, in which case in a manner the noncritical contact resistance in comparison with present-day contact implantations, in which fluctuations in the contact resistance with respect to the aluminum metallization can already occur at implantation doses of less than 1×10¹³ cm⁻². Moreover, the porous-monocrystalline silicon material is embodied with a thickness such that customary defects and slight spikes of the metallization are covered.

The production process is advantageous in which the rendering porous process can be carried out at a favorable point in time during fabrication on account of its high-temperature suitability. In particular, there is freedom of choice as to whether the lightly doped region of the p-conducting well is to be rendered porous and the high p-conducting doping is subsequently introduced by using ion implantation or gas phase diffusion, for example. As an alternative, the previously highly doped region can also be rendered porous. For the anodic oxidation with simultaneous porous etching, an aqueous HF solution or HF solution diluted with organic solvents is used, a 5 molar hydrofluoric acid with a 15 molar C₂H₅OH or an 11.7 modular hydrofluoric acid with a 10.3 molar C₂H₅OH. Before the etching attack, the patterned oxide layer 45 can be protected with a photoresist mask or with a patterned Si₃N₄ layer.

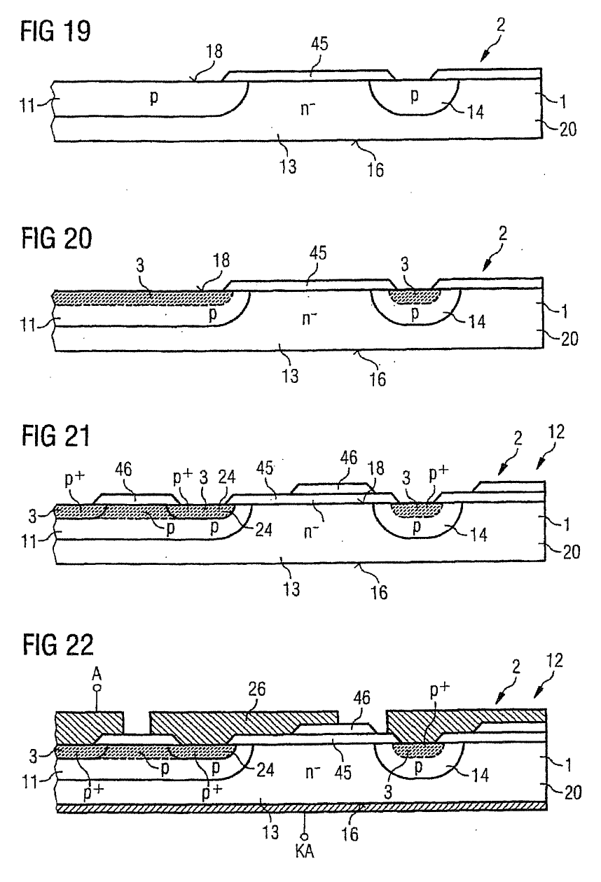

FIGS. 19 to 22 illustrate schematic cross sections through a semiconductor component structure 2 during the production of a switching-robust semiconductor diode 12. In order to increase the switching robustness of the diode illustrated in FIGS. 16 to 18, in the case of this diode a field plate structure is additionally provided in the edge region of the anode 11 and a corresponding protective ring is introduced in the edge region of the semiconductor structure.

In this respect, FIG. 19 illustrates a monocrystalline silicon body 1, in which two p-conducting regions are introduced into the n-conducting silicon body 1 using an oxide mask by using a patterned oxide layer 45. This involves using a diffusion or ion implantation method which does not destroy the monocrystallinity in the p-conducting regions and therefore forms a pn junction in the silicon body both for the anode 11 and for the protective ring region 14.

FIG. 20 illustrates that a porous-monocrystalline silicon region 3 is then in each case introduced partially into the p-conducting regions of the anode 11 and of the protective ring region 14. For this purpose, the patterned oxide 45 can be provided with a patterned protective or resist layer in order to protect it against the etching attack.

After the removal of the protective or resist layer illustrated, a second patterned oxide layer 46 is applied to the first patterned oxide layer 45, which is intended to prevent, in the anode region 11, a contact region from arising in the jeopardized vicinity of the lateral edge region. Rather, a terminal region 26 is intended to be reserved for a field plate which is not at anode potential at least momentarily. After the application of the second patterned oxide layer 46, it is then possible to introduce the high dopings for the contact terminal regions of the anode 11, of the field plate 24 and of the protective ring 14. This measure gives rise, in the lateral edge zone of the anode region 11, to a low-impedance p-conducting porous-monocrystalline silicon region 3 that ensures a high switching robustness of the resulting freewheeling diode 12.

FIG. 22 illustrates a schematic cross section through the freewheeling diode 12 of FIG. 21 after the metallization has been applied to the anode region 11, the field plate terminal region 24 and the protective ring region 14. This switching robustness arises because the anode metal of the anode 25 ends laterally far before the end of the anode doping. In addition, the production of the edge field plates usually requires more than one dielectric layer. If the second patterned oxide layer 26 is used for masking the doping of the porous-monocrystalline silicon region, this reduces the injection of charge carriers into the edge region of the freewheeling diode on account of the high lateral bulk resistance in the anode, which improves the switching robustness.

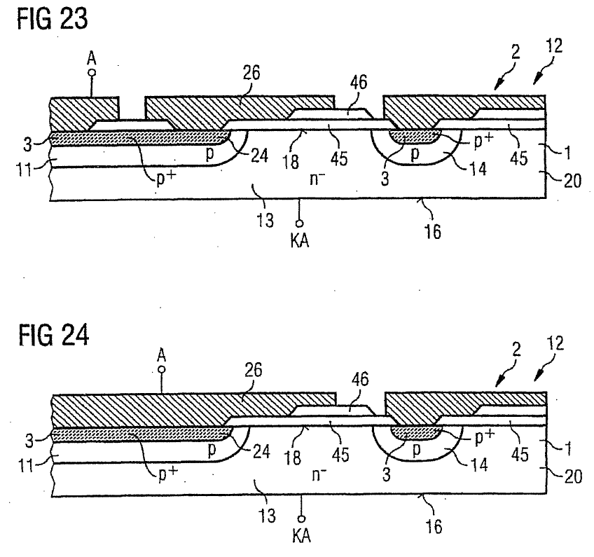

FIGS. 23 and 24 illustrate variants of an embodiment of a freewheeling diode 12 with porous-monocrystalline silicon region 3. These two further variants have a greater injection of charge carriers in the edge regions, but are then simpler to produce. Whereas both an anode electrode A and a field plate 26 and a metallization of the protective ring region 14 are provided in FIG. 23, the field plate electrode is combined with the anode electrode in FIG. 24, such that a smaller edge width arises and this freewheeling diode 12 is therefore particularly well suited to smaller semiconductor chips for lower current intensities with a few amperes or with less than 10 A rated current which do not place such high demands on the switching robustness as can be achieved with the exemplary embodiment in accordance with FIG. 22.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor component comprising:
a monocrystalline semiconductor body; and
wherein the monocrystalline semiconductor body has a semiconductor component structure with regions of a porous-monocrystalline semiconductor.

2. The semiconductor component of claim 1, comprising wherein the semiconductor component structure has a substrate region composed of porous-monocrystalline and highly doped semiconductor material.

3. The semiconductor component of claim 1, comprising wherein the semiconductor component structure has a substrate region composed of porous-monocrystalline and highly doped silicon.

4. The semiconductor component of claim 1, comprising wherein the semiconductor component structure has a source region of a source terminal zone of a MOSFET with porous-monocrystalline and highly doped semiconductor material.

5. The semiconductor component of claim 1, comprising wherein the semiconductor component structure has a body zone region of a MOSFET with porous-monocrystalline semiconductor material.

6. The semiconductor component of claim 1, comprising wherein the semiconductor component structure has a drain region of a drain terminal zone of a MOSFET with porous-monocrystalline and highly doped semiconductor material.

7. The semiconductor component of claim 1, comprising wherein the porous-monocrystalline semiconductor material is arranged in the region of a parasitic bipolar transistor of an IGBT or of a MOSFET.

8. The semiconductor component of claim 1, comprising wherein the porous-monocrystalline semiconductor material is arranged in the body zone of an IGBT or of a MOSFET with a gate structure arranged in a trench structure above the space charge region of the pn junction from the body zone to the drift zone of a drift path.

9. The semiconductor component of claim 1, comprising wherein the porous-monocrystalline semiconductor material is arranged in integrated circuits at positions jeopardized by shunt current.

10. The semiconductor component of claim 1, comprising wherein the semiconductor component structure has an anode region of a semiconductor diode with porous-monocrystalline and highly doped semiconductor material.

11. The semiconductor component of claim 1, comprising wherein the semiconductor component structure has a cathode region of a power diode with porous-monocrystalline and highly doped semiconductor material.

12. The semiconductor component of claim 1, comprising wherein the semiconductor component structure has a protective ring region with porous-monocrystalline and highly doped semiconductor material.

13. The semiconductor component of claim 1, comprising wherein the semiconductor component structure has an emitter region of an IGBT with porous-monocrystalline and highly doped semiconductor material.

14. The semiconductor component of claim 1, comprising wherein the semiconductor component structure has a collector region of an IGBT with porous-monocrystalline and highly doped semiconductor material.

15. A method for producing a monocrystalline semiconductor wafer for semiconductor components with semiconductor component structures having regions composed of porous-monocrystalline semiconductor comprising:
prepatterning a semiconductor wafer with semiconductor component structures;
covering regions of the prepatterned semiconductor wafer which are not intended to have a porosity with a protective layer structure;
anodic oxidation with simultaneous porous etching removal of the monocrystalline semiconductor material to form pores in the monocrystalline semiconductor wafer in the non-covered regions of the semiconductor wafer;
removing the protective layer structure; and
final patterning of the semiconductor wafer to form semiconductor component structures with regions composed of porous-monocrystalline semiconductor.

16. A method for producing a semiconductor component with semiconductor component structures having regions composed of porous-monocrystalline semiconductor material comprising:
prepatterning of a wafer with semiconductor component structures;
covering of the regions of the prepatterned wafer which are not intended to have a porosity with a protective layer structure;
anodic oxidation with simultaneous porous etching removal of the monocrystalline semiconductor material to form pores in the monocrystalline wafer in the non-covered regions of the wafer;
removing the protective layer structure; and
final patterning of the wafer to form semiconductor component structures with regions composed of porous-monocrystalline semiconductor material.

17. The method of claim 15, comprising wherein for rendering a substrate region porous, the rear side of the semiconductor wafer is subjected to anodic oxidation and etched in porous fashion.

18. The method of claim 15, comprising wherein for rendering a substrate region of the wafer porous after completion of a semiconductor component structure based on epitaxial layers of the top side of the wafer, the rear side of the wafer is subjected to anodic oxidation and is etched in porous fashion.

19. The method of claim 15, comprising wherein a substrate region of a charge compensation component or IGBT is rendered porous partially or over the whole area to form porous-monocrystalline semiconductor material by being subjected to anodic oxidation and etching in porous fashion.

20. The method of claim 15, comprising wherein a body zone region of a charge compensation zone component is rendered porous partially or over the whole area to form a charge carrier recombination zone after a patterning of a gate polysilicon layer.

21. The method of claim 15, comprising wherein a doping of regions to be etched in porous fashion is effected after the application of the protective layer structure and before the rendering porous process.

22. The method of claim 15, comprising wherein a doping of regions etched in porous fashion is effected after the rendering porous process.

23. The method of claim 15, comprising wherein a body zone region of a charge compensation component or IGBT is rendered porous partially or over the whole area after a spacer process.

24. The method of claim 15, comprising wherein a body zone region of a charge compensation component or IGBT is rendered porous partially or over the whole area after an introduction of contact windows into an intermediate oxide.

25. The method of claim 15, comprising wherein an anode region and/or a field plate terminal region of a semiconductor diode is rendered porous partially or over the whole area after the introduction of a p-conducting anode region into the top side of a semiconductor body and before the metallization of the anode and/or the field plate;
wherein a cathode region of a semiconductor diode is rendered porously partially or over the whole area after the introduction of an n-conducting cathode region into the rear side of a semiconductor body and before the metallization of the cathode;
wherein a weakly doped p-conducting region between an anode and a field plate terminal is etched in porous fashion before a metallization of anode and field plate; and
wherein an alcohol and hydrofluoric acid are used during the anodic oxidation and simultaneous etching.
